(19) United States
(12) Patent Application Publication
(10) Pub. No.: US 2002/0009877 A1
(43) Pub. Date: Jan. 24, 2002

(54) Method for forming via holes by using retardation layers to reduce overetching

(75) Inventors: Shyan-Yhu Wang, Taichung City (TW); Jyh-Jian Huang, Hsin-Chu City (TW); Kun-Lin Wu, Chu-Tung Chen (TW)

Correspondence Address: LOWE HAUPTMAN GILMAN & BERNER, LLP, Suite 310, 1700 Diagonal Road, Alexandria, VA, 22314, US

(73) Assignee: United Microelectronics Corp., Taiwan, R.O.C.

(21) Appl. No.: 09/875,038

(22) Filed: Jun. 7, 2001

Related U.S. Application Data
(62) Division of application No. 09/616,056, filed on Jul. 13, 2000.

(51) Int. Cl. H01L 21/4763

(52) U.S. Cl. 438/637

(57) ABSTRACT

A method for forming vias between a multi-layer structure and an interconnect is disclosed. The method is practiced on a semiconductor substrate having a conductive region and a multi-layer structure which has a first conductive layer on top. A retardation layer is formed over the first conductive layer and a dielectric layer is formed over the entire surface of the multi-layer structure, the entire surface of the conductive region and over the surface of the substrate. A first via hole is formed through both the dielectric layer and the retardation layer to expose a portion of the first conductive layer. A second via hole is formed through the dielectric layer to expose a portion of the conductive region. A first via plug is formed in the first via hole to electrically contact the first conductive layer and a second via plug is formed in the second via hole to electrically contact the conductive region. A patterned second conductive layer is formed as an interconnect over the dielectric layer and the via plugs.

### BACKGROUND OF THE INVENTION

1. Field of the Invention

The present invention relates to a method for forming vias and more particularly to a method for forming vias using a retardation layer to reduce overetching during the formation of vias.

2. Description of the Prior Art

The design of a multi-level metal (MLM) system is aimed at reducing lead resistances and capacitances without compromising yield and reliability. Such a system can be designed by repeating the techniques for via and metal patterning. In general, contact openings or via openings are formed in a dielectric layer, and are filled with an appropriate conductor, typically aluminum or tungsten, to form vertical connections to semiconductor devices or interconnects.

Capacitors are extensively used in electronic devices for storing electric charges and also broadly used in many kinds of semiconductor device, for example, in dynamic random access memory. A capacitor essentially comprises two electrodes and a dielectric which locates between the two electrodes. An electrode is usually a conductor plate, such as a metal layer. And the material of an electrode comprises copper, aluminum and polysilicon. Besides, the dielectric is usually a material with high dielectric constant, and comprises tantalum oxide, barium strontium titanate (BST), lead zirconium titanate (PZT), oxide-nitride-oxide(ONO), silicon nitride, silicon oxynitride, and silicon dioxide.

In general, the method for connecting capacitors with interconnects comprises the following steps. First, as shown in FIG. 1, a substrate 210 with a conductive region 221 and a capacitor is provided, wherein the capacitor is composed of a upper electrode 230, a intermetal dielectric 225, and a lower electrode 220. Second, via holes are formed in a dielectric layer 250 over the capacitor. Next, the via holes are filled with metal plugs 291, 292. Finally, an interconnect 300 is formed over the dielectric layer 250 and the metal plugs 291,292. Providing the via hole over a capacitor has a shorter depth than the others, an overetching may occur on the surface of the capacitor electrode during the formation of the via holes. The overetching will make the surface of capacitor electrode rough. And then a poor contact interface will be formed between the capacitor electrode and the via plug, and will cause a high contact resistance.

The problem caused by overetching can be solved by using a retardation layer capped on the surface of capacitor electrode. The retardation layer has a smaller etching rate than the dielectric layer has, so that the overetching can be reduced.

### SUMMARY OF THE INVENTION

It is an object of the present invention to provide a method for forming via holes by using retardation layers to retard the etching rate.

It is another object of the present invention to provide a method for reducing overetching during the formation of vias between the capacitors and the interconnects. And such method will provide vias with lower contact resistance.

A further object of the present invention is to provide a method for forming vias with different depth in one etch step.

In accordance with the aspect of the invention, a method provided for forming vias between a multi-layer structure and a conductive interconnect comprises following steps. First, a substrate having a conductive region and a multi-layer structure is provided, wherein the multi-layer structure has a top conductive layer, a bottom layer and a sidewall. Then, a retardation layer is deposited over the top conductive layer. Next, a dielectric layer is formed to cover the multi-layer structure, the conductive region and the substrate. Then, an etching process is performed to form via holes. There are two via holes formed in the dielectric layer, one via hole is formed to expose a portion of the top conductive layer, the other is formed to expose a portion of the conductive region. Next, the two via holes are filled by tungsten plug. Finally, a patterned conductive layer is formed as an interconnect over the dielectric layer and the two via plug. Then the connection is completed.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a cross-sectional diagram illustrating a conventional method for making vias between a capacitor and an interconnect.

FIG. 2A to FIG. 2D are cross-sectional diagrams illustrating the various steps in a method for making vias between a multi-layer structure and an interconnect according to the present invention; and

FIG. 3A to FIG. 3D are cross-sectional diagrams illustrating the various steps in another method for making vias between a capacitor and an interconnect according to the present invention.

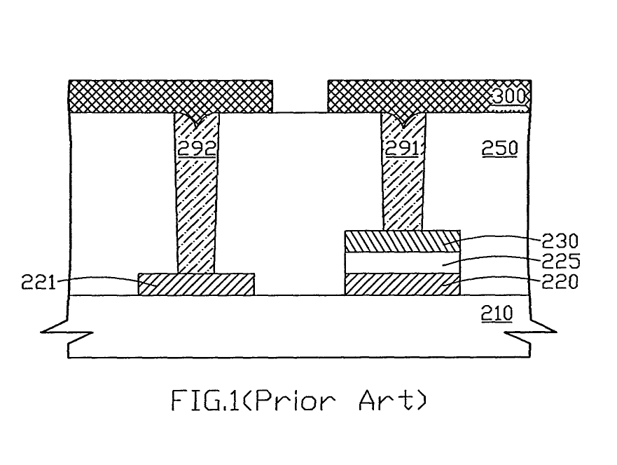

### DESCRIPTION OF THE PREFERRED EMBODIMENT

The making and use of the presently preferred embodiments are discussed below in detail. The specific embodiments discussed are merely illustrative of specific ways to make and use the invention, and do not limit the scope of the invention.

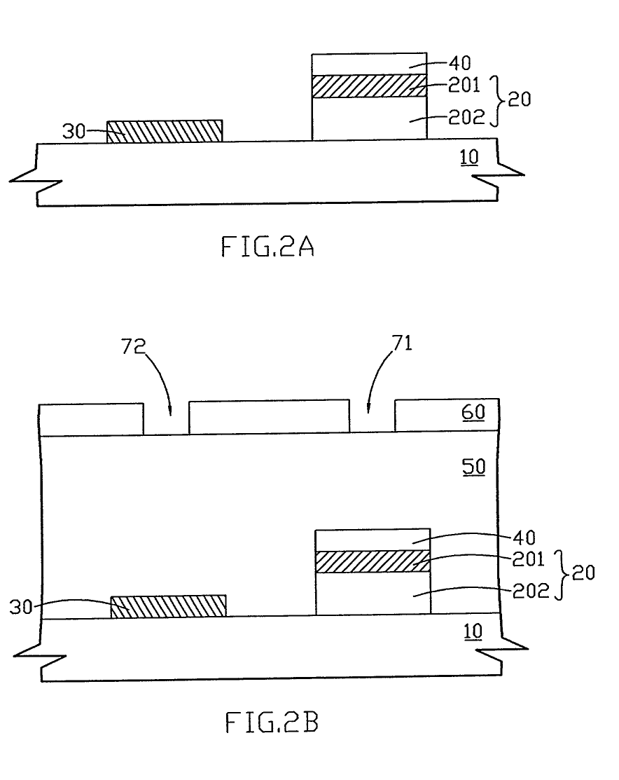

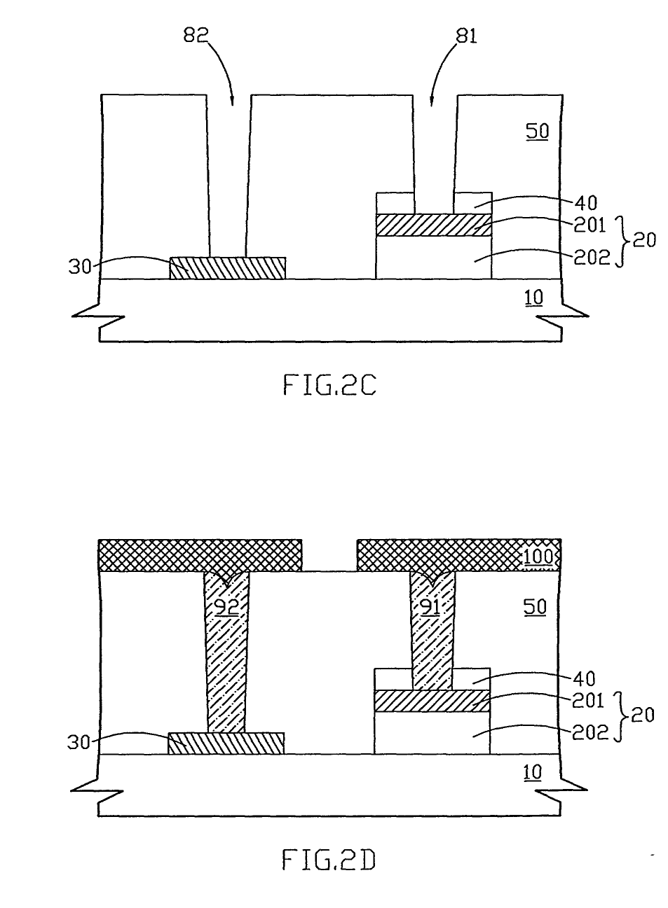

In a preferred embodiment of the present invention, a method provided for forming vias between a multi-layer structure and an interconnect comprises following steps. First, as shown in FIG. 2A, a substrate 10 having a multi-layer structure 20 and a conductive region 30 is provided, wherein the multi-layer structure 20 has a top conductive layer 201, a bottom layer 202 and a sidewall. The material of the top conductive layer 201 comprises aluminum, copper, titanium nitride and polysilicon. Then, a retardation layer 40 is deposited over the top conductive layer 201 of the multi-layer structure 20. The retardation layer 40 has a first etching rate smaller than the following dielectric layer has. The thickness of the retardation layer 40 depends on the difference in etching rate between the retardation layer and the dielectric layer where the via holes is formed, and on the difference in depth of via holes. The material of the retardation layer 40 includes oxide-nitride-oxide (ONO), silicon oxynitride (SiON), and silicon nitride (SiN).

Next, as show in FIG. 2B, a dielectric layer 50 is formed by high density plasma chemical vapor deposition over the entire surface of the multi-layer structure 20, over the entire surface of the conductive region 30 and the surface of the substrate 10. The dielectric layer 50 has a second etching rate in the range of 4500-7000 KA/min, larger than the first etching rate of the retardation layer 40. The material of the dielectric layer 50 comprises silicon rich oxide (SRO), plasma-enhanced tetraethoxysilane (PETEOS) oxide, spin on glass (SOG), and high density plasma oxide. Next, the dielectric layer 50 is planarized by chemical-mechanical polishing. Then, a mask 60 is deposited on the dielectric layer 50 and patterned to define the via opening. There are two openings formed in the mask 60, the first opening 71 is located over the retardation layer 40, and the second opening 72 is located over the conductive region 30.

And then a dry etching process, such as a fluorocarbon based plasma etch, is performed to form two via holes. As shown in FIG. 2C, the first via hole 81 is formed beneath the first opening 71, through both the dielectric layer 50 and the retardation layer 40, and to expose a portion of the top conductive layer 201. And the second via hole 82 is formed beneath the second opening 72, through the second dielectric layer 50, and to expose a portion of the conductive region 30. After the etching process is completed, the mask 60 is then stripped.

Next, as shown in FIG. 2D, the two via holes are filled by tungsten plug with etch back. The first tungsten plug 91 is formed to electrically contact the top conductive layer 201. And the second tungsten plug 92 is formed to electrically contact the conductive region 30. Finally, a patterned conductive layer is formed as an interconnect 100 over the dielectric layer 50 and the two via plugs. The material of the interconnect 100 comprises aluminum, copper, and polysilicon.

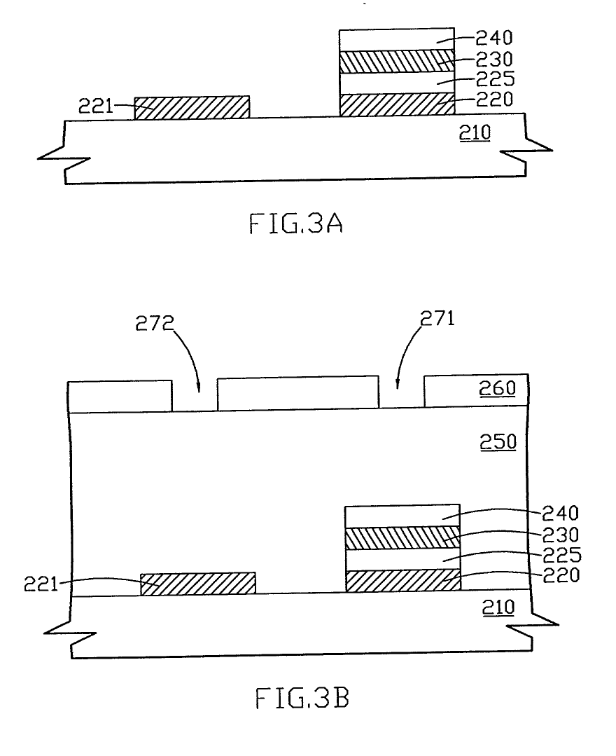

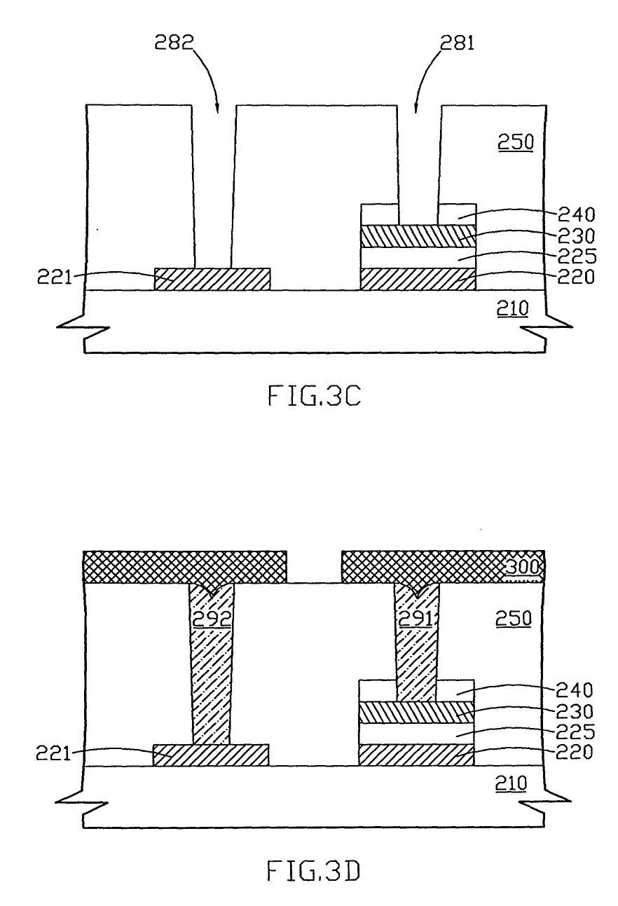

In another preferred embodiment of the present invention, a method for forming vias between a capacitor and an interconnect comprises following steps. First, a semiconductor substrate 210 is provided, as shown in FIG. 3A. Then, a first conductive layer is deposited on the substrate 210 and is patterned to form a conductive region 221 and a lower electrode 220 of a capacitor. The possible material of the first conductive layer comprises aluminum, copper, titanium nitride and polysilicon. Second, a first dielectric layer 225 with high dielectric constant is formed over the lower electrode 220. The material of the first dielectric layer 225 includes tantalum oxide (Ta₂O₅), barium strontium titanate (BST), lead zirconium titanate (PZT), oxide-nitride-oxide (ONO), silicon nitride, silicon oxynitride and silicon dioxide. Next, a second conductive layer is formed over the dielectric layer 225 as the upper electrode 230 of the capacitor. The material of the upper electrode 230 comprises aluminum, copper, titanium nitride and polysilicon. Then, a retardation layer 240 is deposited over the upper electrode 230. The retardation layer 240 has a first etching rate smaller than the following dielectric layer has. The thickness of the retardation layer 240 depends on the difference in etching rate between the retardation layer and the dielectric layer where the via holes, and on the difference in depth of via holes. The material of the retardation layer 240 includes oxide-nitride-oxide (ONO), silicon oxynitride (SiON), and silicon nitride (SiN).

Next, as show in FIG. 3B, a second dielectric layer 250 is formed by high density plasma chemical vapor deposition over the surface of the retardation layer 240, over the entire surface of the conductive region 221, over the surface of the substrate 2 10, and over the sidewall of the capacitor composed of the lower electrode 220, the first dielectric layer 225, and the upper electrode 230. The second dielectric layer 250 has a second etching rate in the range of 4500-7000 KA/min, larger than the first etching rate of the retardation layer 240. The material of the dielectric layer 250 comprises silicon rich oxide (SRO), plasma-enhanced tetraethoxysilane (PETEOS) oxide, spin on glass (SOG), and high density plasma oxide. Next, the second dielectric layer 250 is planarized by chemical-mechanical polishing. Then, a mask 260 having two opening is formed over the second dielectric layer 250. The first opening 271 in the mask 260 is over the retardation layer 240, and the second opening 272 in the mask 260 is over the conductive region 221.

Next, as shown in FIG. 3C, a dry etching process, such as a fluorocarbon based plasma etch, is performed to form two via holes. The first via hole 281 is formed beneath the first opening 271, through both the second dielectric layer 250 and the retardation layer 240, and to expose a portion of the upper electrode 230. And the second via hole 282 is formed beneath the second opening 272, through the second dielectric layer 250, and to expose a portion of the conductive region 221. After the etching process is completed, the mask 260 is then stripped.

Next, as shown in FIG. 3D, the two via holes are filled by tungsten plug with etch back. The first tungsten plug 291 is formed to electrically contact the upper electrode 230. And the second tungsten plug 292 is formed to electrically contact the conductive region 221. Finally, a patterned third conductive layer is formed as an interconnect 300 over the second dielectric layer 250 and the two via plugs. The material of the interconnect 300 comprises aluminum, copper, and polysilicon.

Although specific embodiments have been illustrated and described, it will be obvious to those skilled in the art that various modifications may be made without departing from what is intended to be limited solely by the appended claims.

What is claimed is:

1. A method for forming vias between a multi-layer structure and an interconnect, said method comprising:
providing a semiconductor substrate having a conductive region and a multi-layer structure, wherein said multi-layer structure has a first conductive layer at the top;
forming a retardation layer over said first conductive layer;
forming a dielectric layer over the entire surface of said multi-layer structure, over the entire surface of said conductive region, and over the surface of said substrate;
forming a first via hole through both said dielectric layer and said retardation layer to expose a portion of said first conductive layer, and a second via hole through said dielectric layer to expose a portion of said conductive region;
forming a first via plug in said first via hole to electrically contact said first conductive layer and a second via plug in said second via hole to electrically contact said conductive region;
forming a patterned second conductive layer as an interconnect over said dielectric layer and said via plugs.

2. The method according to claim 1, wherein material of said first conductive layer is selected from the group consisting of aluminum, copper, titanium nitride and polysilicon.

3. The method according to claim 1, wherein material of said retardation layer is selected from the group consisting of oxide-nitride-oxide (ONO), silicon oxynitride (SiON), and silicon nitride (SiN).

4. The method according to claim 1, wherein material of said dielectric layer comprises silicon dioxide.

5. The method according to claim 4, wherein said silicon dioxide is selected from the group consisting of silicon rich oxide, plasma-enhanced tetraethoxysilane oxide, spin on glass, and high density plasma oxide

6. The method according to claim 1, wherein an etching rate of said retardation layer is smaller than that of said dielectric layer.

7. The method according to claim 1, wherein said via plugs comprise tungsten plugs.

8. The method according to claim 1, wherein material of said patterned second conductive layer is selected from the group consisting of aluminum, copper, and polysilicon.

9. A method for forming vias between a capacitor and an interconnect, said method comprising:
providing a semiconductor substrate;
forming a first conductive layer over said substrate;
patterning and etching said first conductive layer to form a lower electrode of a capacitor and a conductive region;
forming a first dielectric layer over said lower electrode;
forming a second conductive layer over said first dielectric layer as a upper electrode of the capacitor;
forming a retardation layer over said second conductive layer;
forming a second dielectric layer over said retardation layer, over the entire surface of said conductive region, over the surface of said substrate and along the sidewall of said capacitor;.
forming a first via hole through both said second dielectric layer and said retardation layer to expose a portion of said second conductive layer, and a second via hole through said second dielectric layer to expose a portion of said conductive region;
forming a first via plug in said first via hole to electrically contact said upper electrode and a second via plug in said second via hole to electrically contact said conductive region;
forming a patterned third conductive layer as an interconnect over said second dielectric layer and said via plugs.

10. The method according to claim 9, wherein material of said first conductive layer is selected from the group consisting of aluminum, copper, titanium nitride and polysilicon.

11. The method according to claim 9, wherein material of said first dielectric layer is selected from the group consisting of tantalum oxide (Ta₂O₅), barium strontium titanate (BST), lead zirconium titanate (PZT), oxide-nitride-oxide (ONO), silicon nitride, silicon oxynitride and silicon dioxide.

12. The method according to claim 9, wherein material of said second conductive layer is selected from the group consisting of aluminum, copper, titanium nitride and polysilicon.

13. The method according to claim 9, wherein material of said retardation layer is selected from the group consisting of oxide-nitride-oxide (ONO), silicon oxynitride (SiON), and silicon nitride (SiN).

14. The method according to claim 9, wherein material of said second dielectric layer comprises silicon dioxide.

15. The method according to claim 14, wherein said silicon dioxide is selected from the group consisting of silicon rich oxide, plasma-enhanced tetraethoxysilane oxide, spin on glass, and high density plasma oxide

16. The method according to claim 9, wherein an etching rate of said retardation layer is smaller than that of said second dielectric layer.

17. The method according to claim 9, wherein said via plugs comprise tungsten plugs.

18. The method according to claim 9, wherein material of said third conductive layer is selected from the group consisting of aluminum, copper, and polysilicon.
